(19) United States
(12) Patent Application Publication
(10) Pub. No.: US 2022/0416107 A1
(43) Pub. Date: Dec. 29, 2022

(54) BIFACIAL TANDEM PHOTOVOLTAIC CELLS AND MODULES

(71) Applicant: Arizona Board of Regents on behalf of Arizona State University, Scottsdale, AZ (US)

(72) Inventors: Zhengshan YU, Gilbert, AZ (US); Zachary HOLMAN, Phoenix, AZ (US); Arthur ONNO, Tempe, AZ (US); Nathan RODKEY, Chandler, AZ (US)

(21) Appl. No.: 17/756,604

(22) PCT Filed: Dec. 21, 2020
(86) PCT No.: PCT/US2020/066470

§ 371 Date: May 27, 2022

Related U.S. Application Data
(60) Provisional application No. 62/951,733, filed on Dec. 20, 2019.

(51) Int. Cl. H01L 31/0725; H01L 31/043; H01L 27/30

(52) U.S. Cl. CPC H01L 31/0725; H01L 31/043; H01L 27/302

(57) ABSTRACT

A tandem photovoltaic cell includes a top cell having a first absorber and a bottom cell having a second absorber. The top cell and the bottom cell are electrically coupled in series. The top cell is configured to receive solar radiation through a first surface of the top cell and to transmit photons through a second surface of the top cell to the bottom cell, and the bottom cell is configured to receive the photons from the top cell through a first surface of the bottom cell and to receive solar radiation through a second surface of the bottom cell. A photovoltaic module includes a multiplicity of the tandem photovoltaic cells.

### CROSS-REFERENCE TO RELATED APPLICATION

This application claims the benefit of U.S. Patent Application No. 62/951,733 entitled “BIFACIAL TANDEM PHOTOVOLTAICS” and filed on Dec. 20, 2019.

### TECHNICAL FIELD

This invention relates to bifacial, two-terminal tandem photovoltaic cells and modules.

### BACKGROUND

Tandem photovoltaic cells pair two photovoltaic sub-cells having semiconductor absorbers with complementary bandgap energies to more efficiently convert sunlight into electrical energy than either sub-cell could independently. Example semiconductor absorbers that may be paired include a perovskite material with silicon, and a perovskite material with a perovskite material having a different composition. One sub-cell, called the top cell, is on the sunward side of the tandem photovoltaic cell; the other, called the bottom cell, receives only the light transmitted through the top cell if the rear surface of the bottom cell is metal or otherwise opaque. One configuration for a tandem photovoltaic cell is a two-terminal tandem, in which one sub-cell is electrically coupled to the other in series by a serial interconnection in the form of a recombination layer or junction.

### SUMMARY

The present disclosure describes various implementations of bifacial, two-terminal tandem photovoltaic cells and modules.

In a first general aspect, a tandem photovoltaic cell includes a top cell having a first absorber and a bottom cell having a second absorber. The top cell and the bottom cell are electrically coupled in series. The top cell is configured to receive solar radiation through a first surface of the top cell and to transmit photons through a second surface of the top cell to the bottom cell, and the bottom cell is configured to receive the photons from the top cell through a first surface of the bottom cell and to receive solar radiation through a second surface of the bottom cell.

A second general aspect includes a photovoltaic module having a multiplicity of the tandem photovoltaic cells of the first general aspect. In the photovoltaic module, each tandem photovoltaic cell is electrically coupled to at least one other tandem photovoltaic cell of the multiplicity of tandem photovoltaic cells. A first side of the photovoltaic module is proximate the first surface of each top cell of the multiplicity of tandem photovoltaic cells, and a second side of the photovoltaic module is proximate the second surface of each bottom cell of the multiplicity of tandem photovoltaic cells.

Implementations of the first and second general aspects may include one or more of the following features.

In some implementations, a bandgap energy of the first absorber exceeds a bandgap energy of the second absorber. The bandgap energy of the first absorber typically exceeds the bandgap energy of the photons. The bandgap energy of the first absorber can be in a range between about 1.5 eV and about 2.1 eV. The bandgap energy of the second absorber can be in a range between about 1 eV and about 1.5 eV.

In some implementations, the first absorber includes perovskite, the second absorber includes perovskite, or both.

In some implementations, the second absorber includes silicon. When the second absorber includes silicon, the bottom cell can be a silicon heterojunction cell, a tunnel-oxide-passivated contact (TOPCon) cell, a passivated-emitter-rear-contact (PERC) cell, or an aluminum-back-surface-field (Al-BSF) cell. When the second absorber includes silicon, the first absorber can include perovskite.

In some implementations, the second surface of the bottom cell is opposite the first surface of the top cell. The top cell and the bottom cell are electrically coupled in series through an optically transparent, electrically conductive layer. The top cell and the bottom cell can be electrically coupled in series through a doped semiconductor layer or layers. When there are two doped semiconductor layers, the doped semiconductor layers typically have opposite doping polarities.

Implementations of the second general aspect may include one or more of the following features.

In some implementations, each tandem photovoltaic cell is electrically coupled to the at least one other tandem photovoltaic cell of the multiplicity of tandem photovoltaic cells with an electrically conductive material that electrically couples, through an opening between each tandem photovoltaic cell and the at least one other tandem photovoltaic cell, a first electrically conductive material on a sunward side of the multiplicity of tandem photovoltaic cells and a second electrically conductive material on a rear side of the multiplicity of tandem photovoltaic cells.

In some implementations, each tandem photovoltaic cell is electrically coupled in parallel to the at least one other tandem photovoltaic cell. In some implementations, each tandem photovoltaic cell is electrically coupled in series to the at least one other tandem photovoltaic cell.

In some implementations, the photovoltaic module includes a first protective layer proximate the first side of the photovoltaic module and a second protective layer proximate the second side of the photovoltaic module, and the multiplicity of tandem photovoltaic cells is positioned between the first protective layer and the second protective layer. The second protective layer is configured to transmit solar radiation to the second surface of each bottom cell of the multiplicity of tandem photovoltaic cells. Each bottom cell of the multiplicity of tandem photovoltaic cells is configured to receive solar radiation through the second protective layer.

Advantages of the bifacial, two-terminal tandem photovoltaic cells and modules described herein include an increase in electrical energy output and greater stability of the top and bottom cell absorbers relative to monofacial, two-terminal photovoltaic cells. The bifacial, two-terminal tandem photovoltaic cells are well-suited for photovoltaic cells and modules mounted above surfaces with high albedo that reflect sunlight to the second surface of the bottom cell, and are typically less prone to degradation under light, heat, moisture, and other stressors. Another advantage of the bifacial, two-terminal tandem photovoltaic cells and modules includes ease of manufacturing relative to bifacial, four-terminal counterpart. In one example, two-terminal tandem photovoltaic cells have two fewer electrical terminals than four-terminal tandem photovoltaic cells. In some cases, two-terminal tandem photovoltaic modules are configured to operate without power electronics used in or with four-terminal tandem photovoltaic modules to separately optimize the top-cell and bottom-cell strings.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF DRAWINGS

FIG. 1 is a cross-sectional view of a bifacial tandem photovoltaic cell.

FIG. 2 is a cross-sectional view of a bifacial tandem photovoltaic cell.

FIG. 3 is a cross-sectional view of a bifacial tandem photovoltaic cell having a perovskite top cell and a silicon heterojunction bottom cell.

FIG. 4 is a cross-sectional view of a bifacial tandem photovoltaic cell having a perovskite top cell and a silicon double-sided TOPCon bottom cell.

FIG. 5 is a cross-sectional view of a bifacial tandem photovoltaic cell having a perovskite top cell and a silicon single-sided TOPCon bottom cell.

FIG. 6 is a cross-sectional view of a bifacial tandem photovoltaic cell having a perovskite top cell and a silicon PERC bottom cell.

FIG. 7 is a cross-sectional view of a bifacial tandem photovoltaic cell, in the superstrate configuration, having a perovskite top cell and a perovskite bottom cell.

FIG. 8 is a cross-sectional view of a bifacial tandem photovoltaic cell, in the substrate configuration, having a perovskite top cell and a perovskite bottom cell.

FIG. 9 is a cross-sectional view of a bifacial tandem photovoltaic module formed from freestanding bifacial tandem photovoltaic cells.

FIG. 10 is a cross-sectional view of a bifacial tandem photovoltaic module formed from bifacial tandem photovoltaic cells fabricated on a superstrate.

FIG. 11 is a cross-sectional view of a bifacial tandem photovoltaic module formed from bifacial tandem photovoltaic cells fabricated on a substrate.

### DETAILED DESCRIPTION

This disclosure describes a bifacial, two-terminal, tandem photovoltaic cell. As used herein, a “bifacial” photovoltaic cell generally refers to a photovoltaic cell in which two opposite sides of the photovoltaic cell are configured to receive light. As used herein, a “tandem” photovoltaic cell generally refers to a photovoltaic cell that includes two photovoltaic sub-cells, each sub-cell configured to absorb sunlight and convert it to electricity, with the absorber in the first sub-cell having a different bandgap than the absorber in the second sub-cell. The photovoltaic cell has a first side configured to face the sun (i.e., a “sunward” side) and a second side opposite the first side (i.e., a “rear” side). The first sub-cell (i.e., the sub-cell configured to face the sun, referred to herein as the “top cell”) absorbs and converts to electricity higher-energy photons and transmits lower-energy photons to the second sub-cell. The second sub-cell (i.e., the sub-cell opposite the first sub-cell, referred to herein as the “bottom cell”) is optically coupled to the first sub-cell, and absorbs and converts to electricity photons transmitted through the top cell. As used herein, a material (e.g., a layer or component) that transmits photons allows the photons to pass through the material. As used herein, a “transparent” material generally refers to an “optically transparent” material that transmits photons having an energy in the range of interest.

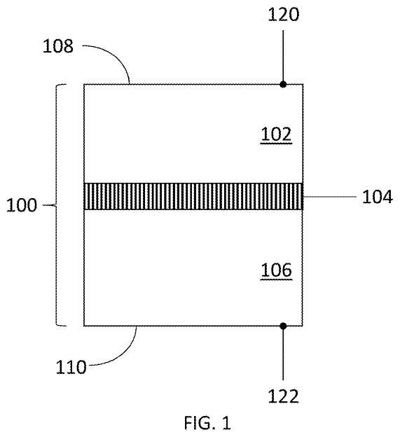

The second sub-cell also absorbs and converts to electricity reflected light incident upon the second sub-cell from the ground or other surface proximate the rear side of the tandem photovoltaic cell. The first sub-cell and the second sub-cell are coupled in series with a conductive material. As used herein, a “conductive” material generally refers to an electrically conductive (low resistance) material, and “electrically coupled” includes electrically connected (e.g., directly electrically connected). The tandem photovoltaic cell includes a first electrically conductive terminal in electrical contact with the first sub-cell and a second electrically conductive terminal in electrical contact with the second sub-cell. While examples of photovoltaic cells and modules are described with respect to FIGS. 1-11, other embodiments can have one or more additional layers or components, or can have the same layers or components arranged in a different order. In some embodiments, one or more of the described components are omitted.

FIG. 1 is a cross-sectional view of photovoltaic cell 100. Photovoltaic cell 100 includes top cell 102, serial interconnection 104, and bottom cell 106. Top cell 102 includes outer (i.e., “front” or “sunward facing”) surface 108. Bottom cell 106 includes outer (i.e., “rear” or “non-sunward facing”) surface 110. Serial interconnection 104 forms an electrical contact between top cell 102 and bottom cell 106, and couples top cell 102 and bottom cell 106 in series. Serial interconnection 104 can be an interface or a layer between top cell 102 and bottom cell 106, and allows light to be transmitted from top cell 102 through serial interconnection 104 and into bottom cell 106. Electrical terminals 120 and 122, electrically coupled to top cell 102 and bottom cell 106, respectively, are configured to have opposite polarities (i.e., a positive polarity and a negative polarity). Top cell 102 is configured to receive solar radiation incident upon front surface 108. Top cell 102 is configured to absorb a higher-energy portion of the solar spectrum and transmit a lower-energy portion of the solar spectrum to serial interconnection 104. Serial interconnection 104 is configured to transmit at least a portion of the solar spectrum transmitted through top cell 102 (e.g., photons having an energy between that of the bandgap of the absorber of top cell 102 and the bandgap of the absorber of the bottom cell 106). Bottom cell 106 is configured to receive solar radiation incident upon front surface 108 and transmitted through top cell 102 and serial interconnection 104. Bottom cell 106 is configured to absorb at least one energy of light that is transmitted through top cell 102 and serial interconnection 104. Bottom cell 106 is also configured to receive solar radiation incident on rear surface 110. Bottom cell 106 is configured to absorb a portion of the solar spectrum incident on rear surface 110.

In some implementations, photovoltaic cell 100 is oriented such that light arriving directly from the sun is incident upon front surface 108. In one example, front surface 108 of top cell 102 has the same surface area or approximately the same surface area as rear surface 110 of bottom cell 106, so that top cell 102 completely covers bottom cell 106 and has outer edges that align with outer edges of bottom cell 106. In this example, some of the light incident on top cell 102 is transmitted through top cell 102 and serial interconnection 104 to bottom cell 106. In this orientation, light reflected from the ground or other surfaces on the rear side of photovoltaic cell 100 can be incident on rear surface 110. In accordance with the transmittance and absorptance of top cell 102, serial interconnection 104, and bottom cell 106, top cell 102 can thus absorb light arriving directly from the sun, and bottom cell 106 can absorb light arriving directly from the sun and light reflected from the ground or other surfaces proximate rear surface 110 of photovoltaic cell 100.

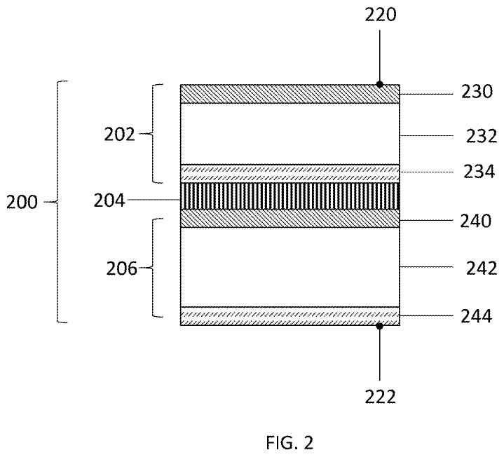

In some implementations, the top and bottom cells of a bifacial tandem photovoltaic cell each have an absorber and one or more contact layers. FIG. 2 is a cross-sectional view of photovoltaic cell 200. Photovoltaic cell 200 includes top cell 202, serial interconnection 204, bottom cell 206, electrical terminal 220, and electrical terminal 222. Top cell 202 includes front contact 230, absorber 232, and rear contact 234. Bottom cell 206 includes front contact 240, absorber 242, and rear contact 244.

Top cell 202 generates electrical power by absorbing light in absorber 232 and separating the photogenerated charge carriers between front contact 230 and rear contact 234. Bottom cell 206 similarly generates electrical power by absorbing light in absorber 242 and separating the photogenerated charge carriers between front contact 240 and rear contact 244. The current density generated by each sub-cell (i.e., top cell 202 and bottom cell 206) at short circuit is determined at least in part by the absorption of light in its absorber and the efficiency with which the photogenerated carriers are separated and collected in its contacts. The light-to-electricity power conversion efficiency of photovoltaic cell 200 depends at least in part on the short-circuit current densities of the sub-cells, with the maximum efficiency typically occurring when the current densities are equivalent or nearly so. If the sub-cells have unity or near-unity charge collection efficiency, the current density of the sub-cells is matched when the absorptance in absorbers 232 and 242 is matched.

Absorber 232 of top cell 202 includes a semiconducting material having a bandgap energy. As semiconductors absorb photons with energies above their bandgap energy and transmit photons with energies below their bandgap energy, absorber 232 is configured to absorb a higher-energy portion of the solar spectrum and transmit a lower-energy portion of the solar spectrum. In some implementations, the bandgap of absorber 232 is between about 1.5 eV and 2.1 eV. The optimum value may depend at least in part on the absorptance in absorber 242 of bottom cell 206, which may depend at least in part on the bandgap of absorber 242 and the intensity and spectrum of light reflected from the ground or other surfaces on the non-sunward side of photovoltaic cell 200. The intensity and spectrum of light reflected depends, at least in part, on the albedo of the reflecting surface, the separation distance between the reflecting surface and photovoltaic cell 200, and any shading of the reflecting surface by objects such as other photovoltaic cells.

In some implementations, absorber 232 of top cell 202 includes a perovskite material with a bandgap between about 1.5 eV and 2.1 eV. In other implementations, absorber 232 of top cell 202 includes gallium arsenide or an alloy of group III and V elements with a bandgap between about 1.5 eV and 2.1 eV. In other implementations, absorber 232 of top cell 202 includes cadmium telluride or an alloy of group II and VI elements with a bandgap between about 1.5 eV and 2.1 eV. In other implementations, absorber 232 of top cell 202 includes copper indium gallium diselenide or a chalcogenide material with a bandgap between about 1.5 eV and 2.1 eV.

Absorber 242 of bottom cell 206 typically includes a semiconducting material having a bandgap energy that is smaller than the bandgap energy of absorber 232. Absorber 242 is thus configured to absorb at least a lower energy portion of the solar spectrum than absorber 232. In some implementations, the bandgap of absorber 242 is between about 1.0 eV and about 1.5 eV. The optimum value can depend at least in part on the absorptance in absorber 232 of top cell 202, as well as the intensity and spectrum of light reflected from the ground or other surfaces proximate the rear side of photovoltaic cell 200.

In some implementations, absorber 242 of bottom cell 206 includes monocrystalline or polycrystalline silicon, which has a bandgap of about 1.12 eV. In other implementations, absorber 242 of bottom cell 206 includes a perovskite material with a bandgap between about 1.0 eV and 1.5 eV. In other implementations, absorber 242 of bottom cell 206 includes gallium arsenide, which has a bandgap of about 1.42 eV, or an alloy of group III and V elements with a bandgap between about 1.0 eV and 1.5 eV. In other implementations, absorber 242 of bottom cell 206 includes cadmium selenium telluride, which has a bandgap of about 1.42 eV, or an alloy of group II and VI elements with a bandgap between about 1.0 eV and 1.5 eV. In other implementations, absorber 242 of bottom cell 206 includes copper indium gallium diselenide or a chalcogenide material with a bandgap between about 1.0 eV and 1.5 eV.

Contacts 230, 234, 240, and 244 are configured to passivate the surface of absorbers 232 and 242, selectively extract photogenerated electrons or holes from absorbers 232 and 242, or conduct charge carriers laterally across a surface of a sub-cell. Contacts 230, 234, 240, and 244 can include one or more materials or layers. In some implementations, one material or layer of a contact passivates the surface of an absorber, another material or layer of the contact selectively extracts photogenerated electrons or holes from an absorber, and another material or layer of the contact conducts charge carriers laterally. In other implementations, one material or layer of a contact performs more than one of these roles. At least one material or layer of contact 230 is electrically coupled to electrical terminal 220. At least one material or layer of contact 244 is electrically coupled to electrical terminal 222.

Front contact 230 of top cell 202 transmits at least the portions of the solar spectrum that absorbers 232 and 242 are configured to absorb. That is, front contact 230 transmits photons having energies greater than the bandgap energy of absorber 242. Rear contact 234 of top cell 202 transmits at least the portion of the solar spectrum that absorber 232 does not absorb and that absorber 242 is configured to absorb. That is, rear contact 234 transmits photons having energies between the bandgap energies of absorbers 232 and 242. Front contact 240 of bottom cell 206 transmits at least the portion of the solar spectrum that absorber 232 does not absorb and that absorber 242 is configured to absorb. That is, front contact 240 transmits photons having energies between the bandgap energies of absorbers 232 and 242. Rear contact 244 of bottom cell 206 transmits at least the portion of the solar spectrum that absorber 242 is configured to absorb. That is, rear contact 244 transmits photons having energies greater than the bandgap energy of absorber 242.

Top cell 202 and bottom cell 206 are electrically coupled in series with serial interconnection 204. In some implementations, electrical terminal 220 is configured to be negative and electrical terminal 222 is configured to be positive. In this case, contact 230 is an electron contact, contact 234 is a hole contact, contact 240 is an electron contact, and contact 244 is a hole contact. Serial interconnection 204 then facilitates the recombination of photogenerated holes extracted from absorber 232 through contact 234 with photogenerated electrons extracted from absorber 242 through contact 240. In other implementations, the polarities are reversed, and serial interconnection 204 facilitates the recombination of photogenerated electrons extracted from absorber 232 through contact 234 with photogenerated holes extracted from absorber 242 through contact 240.

In some implementations, serial interconnection 204 is an optically transparent, electrically conductive oxide layer of indium tin oxide, indium zinc oxide, hydrogenated indium oxide, indium tungsten oxide, indium cerium oxide, tin oxide, zinc oxide, zinc tin oxide, any combination thereof, or any other suitable material. In some implementations, serial interconnection 204 is a stack of two highly doped semiconductor layers having opposite doping polarities. As used herein, “highly doped” or “high dopant concentration” typically means having a dopant density or free electron or hole density of at least about 10¹⁸ cm⁻³. The layers may, for example, include nano- or micro-crystalline silicon, nano- or micro-crystalline silicon oxide, polycrystalline silicon, or alloys having group III and VI elements. Recombination occurs when photogenerated electrons in the conduction band of the n-type layer tunnel into the valence band of the p-type layer, or when photogenerated holes in the valence band of the p-type layer tunnel into the conduction band of the n-type layer. Such a serial interconnection can be referred to as a “tunnel junction.” It is also possible that the two highly doped layers that form the tunnel junction also serve the roles of contact 234 to absorber 232 and contact 240 to absorber 242. In this case, serial interconnection 204 can be understood as an interface between these layers rather than an extra element (e.g., layer) that is separate from both sub-cells.

In other implementations, serial interconnection 204 is a bonding layer that adheres top cell 202 to bottom cell 206 and enables charge carrier transport between the sub-cells. In one example, contacts 234 and 240 include metal grid lines, and serial interconnection 204 includes a thin layer of epoxy or other suitable adhesive that bonds the sub-cells such that the metal grid lines are in electrical contact with one another. In one example, serial interconnection 204 includes indium or another suitable metal that is applied to the metal grid lines such that the grid lines on the sub-cells bond and are in electrical contact with one another.

In some implementations, a bifacial tandem photovoltaic cell has a perovskite top cell and a silicon bottom cell. The perovskite top cell can typically be any top cell having an absorber with the perovskite crystal structure ABX₃, where A and B are cations or mixtures of cations and X is an anion or mixtures of anions. The silicon bottom cell can be an amorphous silicon/crystalline silicon heterojunction cell, tunnel-oxide-passivated contact (TOPCon) cell, a passivated-emitter-rear-contact (PERC) cell, or some combination thereof.

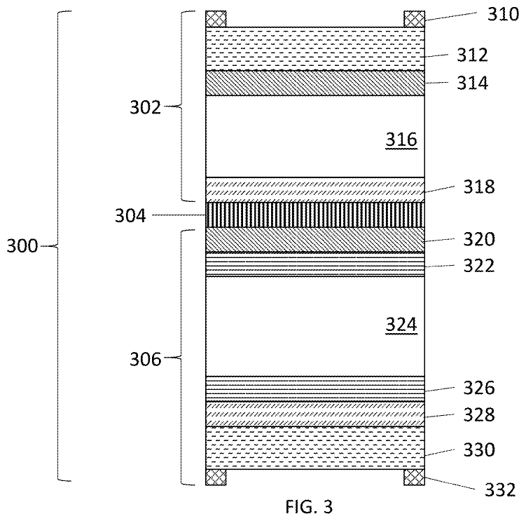

FIG. 3 is a cross-sectional view of photovoltaic cell 300. Photovoltaic cell 300 includes perovskite top cell 302, serial interconnection 304, and silicon heterojunction bottom cell 306. Perovskite top cell 302, from its sunward side to rear side, includes metal grid 310, transparent conductor 312, electron-selective layer 314, perovskite absorber 316, and hole-selective layer 318. In some implementations, the positions of the electron-selective and hole-selective layers are reversed. Electron-selective layers can be referred to as “electron transport layers,” and hole-selective layers can be referred to as “hole transport layers.” Metal grid 310 can include silver, copper, aluminum, tin, nickel, or a combination thereof, and can be screen printed, inkjet printed, evaporated, plated, or otherwise deposited. The metal can be formed into any pattern on the surface of the perovskite solar cell, including, for example, fingers and bus bars. Metal grid 310 can serve as one of the electrical terminals of photovoltaic cell 300. Transparent conductor 312 can include one or more layers of materials such as indium tin oxide, indium zinc oxide, hydrogenated indium oxide, indium tungsten oxide, indium cerium oxide, tin oxide, zinc oxide, zinc tin oxide, or combinations thereof. Each layer can be sputtered, evaporated, spray coated, or otherwise deposited. Transparent conductor 312 is configured to transport photogenerated electrons collected in electron-selective layer 314 laterally to metal grid 310. Electron-selective layer 314 can include one or more materials configured to conduct photogenerated electrons out of perovskite absorber 316 and to resist photogenerated holes. Electron-selective layer 314 can include a low-work-function material (e.g., tin oxide, zinc oxide, titanium oxide, fullerene, fullerene derivatives, or a combination or stack thereof). Here, a “low-work-function” material typically has a work function of less than about 4.5 eV. Perovskite absorber 316 typically has a bandgap energy of about 1.5-1.7 eV (e.g., about 1.55-1.65 eV). Perovskite absorber 316 can have a composition represented by MA_{w}FAₓCs_{1-w-x}Pb(I_{y}Br_{z}Cl_{1-y-z})₃, where MA represents methylammonium, FA represents formamidinium, Cs represents cesium, Pb represents lead, I represents iodide, Br represents bromine, Cl represents chlorine, and w, x, y, z represent relative concentrations chosen to achieve the target bandgap energy. Alternatively, perovskite absorber 316 can have any other suitable composition that achieves the target bandgap energy. Perovskite absorber 316 can be formed by spin coating, blade coating, slot-die coating, gravure coating, roll coating, spray coating, evaporation, sublimation, or any other suitable deposition process. Hole-selective layer 318 can include one or more materials configured to conduct photogenerated holes out of perovskite absorber 316 and to resist photogenerated electrons. Hole-selective layer 318 can include a high-work-function material (e.g., nickel oxide, tungsten oxide, molybdenum oxide, Spiro-OMeTAD, poly(triaryl amine), polyTPD, PFN, PEDOT:PSS, or a combination or stack thereof). Here, a “high-work-function” material typically has a work function of greater than about 4.5 eV.

Serial interconnection 304 is a recombination layer or junction. Serial interconnection 304 can include indium tin oxide, indium zinc oxide, hydrogenated indium oxide, indium tungsten oxide, indium cerium oxide, tin oxide, zinc oxide, zinc tin oxide, or combinations thereof that are sputtered, evaporated, spray coated, or otherwise deposited. In some implementations, serial interconnection 304 is a stack of highly doped n-type and p-type nano- or micro-crystalline silicon, nano- or micro-crystalline silicon oxide, or polycrystalline silicon deposited by plasma-enhanced chemical vapor deposition, hot-wire chemical vapor deposition, low-pressure chemical vapor deposition, sputtering, or any other suitable method.

Silicon heterojunction bottom cell 306, from sunward side to rear side, includes electron-selective layer 320, first passivation layer 322, silicon absorber 324, second passivation layer 326, hole-selective layer 328, transparent conductor 330, and metal grid 332. In some implementations, the positions of the electron-selective and hole-selective layers are reversed in accordance with the polarities of the contacts of perovskite top cell 302. Electron-selective layer 320 can include n-type hydrogenated amorphous silicon, amorphous silicon oxide, amorphous silicon carbide, nano- or microcrystalline silicon, nano- or micro-crystalline silicon oxide, or combinations thereof. Electron-selective layer 320 can be made n-type by incorporation of phosphorous into the layer (e.g., by introducing phosphorous-containing precursor gases or vapors during deposition). Passivation layers 322 and 326 can include nominally intrinsic hydrogenated amorphous silicon, amorphous silicon oxide, amorphous silicon carbide, or combinations thereof. Hole-selective layer 328 can include p-type hydrogenated amorphous silicon, amorphous silicon oxide, amorphous silicon carbide, nano- or microcrystalline silicon, nano- or micro-crystalline silicon oxide, or combinations thereof. Hole-selective layer 328 can be made p-type by incorporation of boron into the layer (e.g., by introducing boron-containing precursor gases or vapors during deposition). Layers 320, 322, 326, and 328 can be deposited by plasma-enhanced chemical vapor deposition or hot-wire chemical vapor deposition. In some implementations, silicon absorber 324 is a monocrystalline silicon wafer or a multicrystalline silicon wafer. The silicon wafer can be n-type, p-type, or nominally intrinsic. One or more surfaces of the silicon wafer can be textured with, for example, pyramid, mesa, or isotropic-etch features. Transparent conductor 330 can include one or more layers of materials such as indium tin oxide, indium zinc oxide, hydrogenated indium oxide, indium tungsten oxide, indium cerium oxide, tin oxide, zinc oxide, zinc tin oxide, or combinations thereof that are sputtered, evaporated, spray coated, or otherwise deposited. Metal grid 332 can include, for example, silver, copper, aluminum, tin, nickel, or a combination thereof, and can be screen printed, inkjet printed, evaporated, plated, or otherwise deposited. Metal grid 332 defines openings and can be formed into any pattern on the surface of the silicon solar cell, including, for example, fingers and bus bars. The openings allow light reflected from the ground or other surfaces proximate the rear surface of photovoltaic cell 300 to reach silicon absorber 324. That is, metal grid 332 is not in the form of a continuous opaque layer that blocks transmission of light to silicon absorber 324. In some implementations, metal grid 332 serves as an electrical terminal of photovoltaic cell 300.

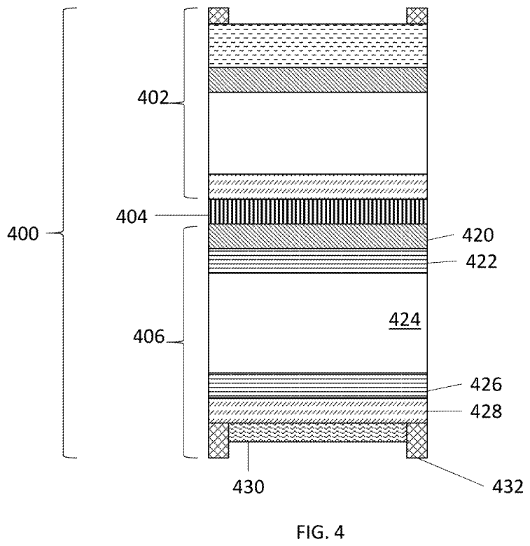

FIG. 4 is a cross-sectional view of photovoltaic cell 400. Photovoltaic cell 400 includes perovskite top cell 402, serial interconnection 404, and silicon double-sided TOPCon bottom cell 406. Perovskite top cell 402 can be the same as perovskite top cell 302 or it can be different. Serial interconnection 404 can be a recombination layer or junction. Serial interconnection 404 can include, for example, indium tin oxide, indium zinc oxide, hydrogenated indium oxide, indium tungsten oxide, indium cerium oxide, tin oxide, zinc oxide, zinc tin oxide, or combinations thereof that are sputtered, evaporated, spray coated, or otherwise deposited. In some implementations, serial interconnection 404 includes a layer of highly doped p-type or n-type nano- or micro-crystalline silicon, nano- or micro-crystalline silicon oxide, or polycrystalline silicon deposited by plasma-enhanced chemical vapor deposition, hot-wire chemical vapor deposition, low-pressure chemical vapor deposition, sputtering, or any other suitable method. In some cases, serial interconnection 404 forms a tunnel junction with polycrystalline silicon 420.

Silicon double-sided TOPCon bottom cell 406, from its sunward side to its rear side, includes first polycrystalline silicon layer 420, first tunnel oxide layer 422, silicon absorber 424, second tunnel oxide layer 426, second polycrystalline silicon layer 428, anti-reflection coating 430, and metal grid 432. Polycrystalline silicon layer 420 can be n-type or p-type, deposited directly as polycrystalline silicon, or deposited as amorphous silicon that is subsequently crystallized. Polycrystalline silicon layer 420 can be made n-type by incorporation of phosphorous into the layer (e.g., by introducing phosphorous-containing precursor gases or vapors during deposition). Polycrystalline silicon layer 420 can be made p-type by incorporation of boron into the layer (e.g., by introducing boron-containing precursor gases or vapors during deposition). Polycrystalline silicon layer 420 can be deposited by plasma-enhanced chemical vapor deposition, hot-wire chemical vapor deposition, low-pressure chemical vapor deposition, sputtering, or any other suitable method. Tunnel oxide layers 422 and 426 can include silicon dioxide, non-stoichiometric silicon oxide, aluminum oxide, or any other dielectric material. The thickness of tunnel oxide layers 422 and 426 can be selected such that photogenerated electrons or holes in silicon absorber 424 transport through tunnel oxide layers 422 and 426, for example by tunneling or conduction through pinholes. In one example, tunnel oxide layers 422 and 426 are silicon dioxide layers having a thickness in a range of about 1 nm to about 1.5 nm. Tunnel oxide layers 422 and 426 can be deposited by plasma-enhanced chemical vapor deposition, hot-wire chemical vapor deposition, or low-pressure chemical vapor deposition; grown by wet chemical oxidation, dry furnace oxidation, or wet furnace oxidation; or otherwise formed with a suitable method. Polycrystalline silicon layer 428 typically has the opposite doping type of polycrystalline silicon layer 420. Silicon absorber 424 can be the same as silicon absorber 324 or it can be different. Anti-reflection coating 430 typically includes a dielectric or otherwise optically transparent material or stack of materials configured to maximize the transmission of light incident upon it from the rear side of photovoltaic cell 400 into silicon absorber 424. In one example, anti-reflection coating 430 is a dielectric layer having a refractive index in a range of about 1.4 to about 2.5 and a thickness in a range of about 50 to about 100 nm. In one example, the dielectric material is silicon nitride. The metal of metal grid 432 can include silver, copper, aluminum, tin, nickel or a combination thereof, and can be screen printed, inkjet printed, evaporated, plated, or otherwise deposited. Metal grid 432 can extend through anti-reflection coating 430 to make electrical contact with polycrystalline silicon layer 428. Metal grid 432 defines openings and can be formed into any pattern on the surface of the silicon solar cell, including, for example, fingers and bus bars. That is, metal grid 432 is not in the form of a continuous opaque layer that blocks transmission of light to silicon absorber 424. In some implementations, metal grid 432 serves as an electrical terminal of photovoltaic cell 400.

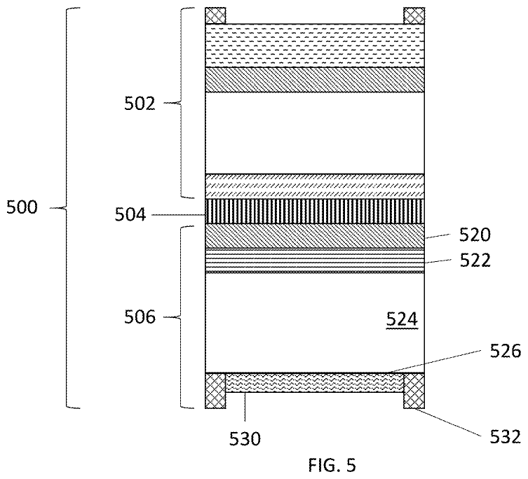

FIG. 5 is a cross-sectional view of photovoltaic cell 500. Photovoltaic cell 500 includes perovskite top cell 502, serial interconnection 504, and silicon single-sided TOPCon bottom cell 506. Perovskite top cell 502 can be the same as perovskite top cell 302 or it can be different. Serial interconnection 504 can be the same as serial interconnection 404 or it can be different.

Silicon single-sided TOPCon bottom cell 506, from its sunward side to its rear side, includes polycrystalline silicon layer 520, tunnel oxide layer 522, silicon absorber 524 having rear surface 526, anti-reflection coating 530, and metal grid 532. Polycrystalline silicon layer 520 can be the same as polycrystalline silicon layer 420 or it can be different. Tunnel oxide layer 522 can be the same as tunnel oxide layer 422 or it can be different. Silicon absorber 524 can be the same as silicon absorber 324 or it can be different. Silicon absorber 524 can have a high dopant concentration in the vicinity of rear surface 526. The dopant can extend from about 0.1 μm to about 10 μm (e.g., about 0.5 μm to about 2) from rear surface 526 into silicon absorber 524. The dopant can be uniformly distributed across rear surface 526, or may be inhomogeneous (e.g., concentrated in certain regions). In one example, the dopant is concentrated in regions in which metal grid 532 directly contacts silicon absorber 524. The dopant can include any element that contributes free electrons or free holes to the silicon absorber. Suitable examples of dopants include boron, aluminum, and phosphorous. The dopant can be introduced into silicon absorber 524 by diffusion at elevated temperature. In one example, boron is diffused into rear surface 526 of silicon absorber 524 in a furnace from boron tribromide vapor. In one example, aluminum is diffused into rear surface 526 of silicon absorber 524 in a furnace from aluminum paste that forms metal grid 532. Anti-reflection coating 530 can be the same as anti-reflection coating 430 or it can be different. Anti-reflection coating 530 can passivate rear surface 526 of silicon absorber 524, reducing non-radiative recombination of photogenerated electrons and holes at that surface. Anti-reflection coating 530 can include silicon oxide, aluminum oxide, silicon nitride, or combinations or stacks thereof. In one example, anti-reflection coating 530 is a stack of aluminum oxide and silicon nitride. The aluminum oxide can have a thickness in a range of about 5 nm to about 20 nm, and the silicon nitride can have a thickness in a range of about of 40 nm to about 90 nm. Metal grid 532 can include silver, copper, aluminum, tin, nickel or a combination thereof, and can be screen printed, inkjet printed, evaporated, plated, or otherwise deposited. Metal grid 532 can extend through anti-reflection coating 530 in one or more regions to make direct electrical contact with silicon absorber 524. In one implementation, metal grid 532 makes direct electrical contact with a region of silicon absorber 524 that has a high dopant concentration in the vicinity of rear surface 526. In one example, metal grid 532 includes an aluminum paste that fires through anti-reflection coating 530 and diffuses aluminum into rear surface 526 of silicon absorber 524. Metal grid 532 defines openings and can be formed into any pattern on the surface of the silicon solar cell, including, for example, fingers and bus bars. That is, metal grid 532 is not in the form of a continuous opaque layer that blocks transmission of light to silicon absorber 524. In some implementations, metal grid 532 serves as an electrical terminal of photovoltaic cell 500.

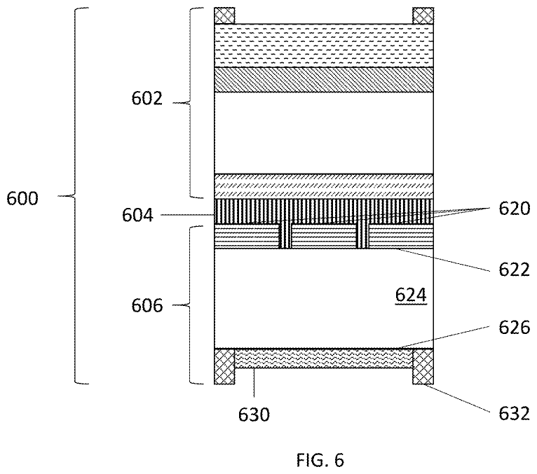

FIG. 6 is a cross-sectional view of photovoltaic cell 600. Photovoltaic cell 600 includes perovskite top cell 602, serial interconnection 604, and silicon PERC bottom cell 606. Perovskite top cell 602 can be the same as perovskite top cell 302 or it can be different. Serial interconnection 604 can be the same as serial interconnection 404 or it may be different.

Silicon PERC bottom cell 606, from its sunward side to rear side, includes passivation layer 620, silicon absorber 624 having front surface 622 and rear surface 626, anti-reflection coating 630, and metal grid 632. Passivation layer 620 passivates front surface 622 of silicon absorber 624, reducing non-radiative recombination of photogenerated electrons and holes at that surface. Passivation layer 620 can include silicon oxide, aluminum oxide, silicon nitride, or combinations or stacks thereof. In one example, passivation layer 620 is a layer of silicon nitride having a thickness in a range of about 10 nm to about 200 nm. Passivation layer 620 can define openings or regions through which light is transmitted to front surface 622 of silicon absorber 624. Silicon absorber 624 can be the same as silicon absorber 524 or it can be different. Silicon absorber 624 can have a high dopant concentration in the vicinity of front surface 622. The dopant may, for example, extend from about 0.1 μm to about 10 μm (e.g., from about 0.5 μm to about 2 μm) from front surface 622 into silicon absorber 624. The dopant can be uniformly distributed across front surface 622, or can be concentrated in certain regions. For example, the dopant can be concentrated in regions in which passivation layer 620 defines openings. Serial interconnection 604 can extend through one or more openings in passivation layer 620 to make direct electrical contact with silicon absorber 624 (e.g., regions of silicon absorber 624 that have a high dopant concentration in the vicinity of front surface 622). The dopant can include any element that contributes free electrons or free holes to the silicon absorber. Examples of suitable dopants include boron and phosphorous. The dopant can be introduced into silicon absorber 624 by diffusion at elevated temperature. In one example, phosphorous is diffused into front surface 622 of silicon absorber 624 in a furnace from phosphorous oxychloride vapor. Anti-reflection coating 630 can be the same as anti-reflection coating 530 or it can be different. Metal grid 632 can be the same as metal grid 532 or it can be different.

Photovoltaic cells 300, 400, 500, and 600 can be fabricated in a variety of sequences. In some fabrication sequences, the silicon bottom cell is first completed. The serial interconnection and perovskite top cell are then deposited atop the perovskite top cell, layer by layer. In one example, indium tin oxide is sputtered, nickel oxide is sputtered, perovskite is slot-die coated, fullerenes are thermally evaporated, tin oxide is deposited by atomic layer deposition, indium tin oxide is sputtered, and low-temperature silver paste is screen printed and cured.

In some implementations, a bifacial tandem photovoltaic cell has a perovskite top cell and a perovskite bottom cell. The perovskite top cell can be any top cell having an absorber with the perovskite crystal structure ABX₃, where A and B are cations or mixtures of cations and X is an anion or mixture of anions. The perovskite bottom cell can be any bottom cell having an absorber with the perovskite crystal structure ABX₃, where A and B are cations or mixtures of cations and X is an anion or mixtures of anions. The absorber of the perovskite bottom cell has a bandgap energy that is smaller than the bandgap energy of the absorber of the perovskite top cell. Bifacial tandem photovoltaic cells having perovskite top and bottom cells that are not freestanding can be fabricated on a support that is not considered to be part of the photovoltaic cell. In some implementations, the photovoltaic cell is fabricated on a superstrate that resides at the sunward side of the completed photovoltaic cell. In other implementations, the photovoltaic cell is fabricated on a substrate that resides at the rear side of the completed photovoltaic cell.

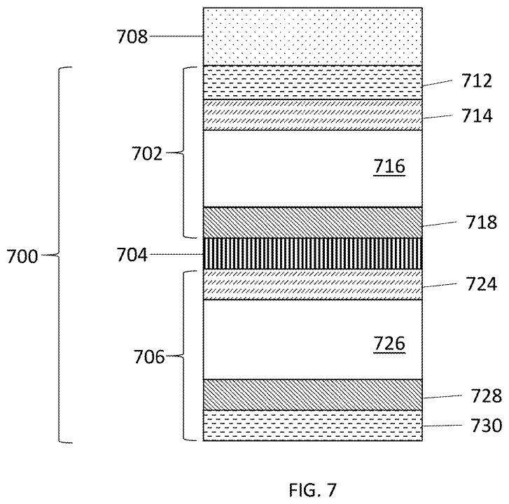

FIG. 7 is a cross-sectional view of photovoltaic cell 700 and superstrate 708. Photovoltaic cell 700 has perovskite top cell 702, serial interconnection 704, and perovskite bottom cell 706. Perovskite top cell 702, from its sunward side to rear side, includes transparent conductor 712, electron-selective layer 714, perovskite absorber 716, and hole-selective layer 718. In some implementations, the positions of the electron-selective and hole-selective layers are reversed. Transparent conductor 712 can include one or more layers of materials such as indium tin oxide, indium zinc oxide, hydrogenated indium oxide, indium tungsten oxide, indium cerium oxide, tin oxide, zinc oxide, zinc tin oxide, or combinations thereof that are sputtered, evaporated, spray coated, or otherwise deposited. Transparent conductor 712 can serve to transport photogenerated electrons collected in electron-selective layer 714 laterally. Transparent conductor 712 can serve as one of the electrical terminals of photovoltaic cell 700. Electron-selective layer 714 can include one or more materials configured to conduct photogenerated electrons out of perovskite absorber 716 and to resist photogenerated holes. Electron-selective layer 714 can include a low-work-function material (e.g., tin oxide, zinc oxide, titanium oxide, fullerene, fullerene derivatives, or a combination or stack thereof). Perovskite absorber 716 can have a bandgap energy of about 1.6 eV to about 1.9 eV or about 1.9 eV to about 2.1 eV. In one example, a composition of perovskite absorber 716 is represented by MA_{w}FAₓCs_{1-w-x}Pb(I_{y}Br_{z}Cl_{1-y-z})₃, where MA represents methylammonium, FA represents formamidinium, Cs represents cesium, Pb represents lead, I represents iodide, Br represents bromine, Cl represents chlorine, and w, x, y, z represent relative concentrations chosen to achieve the target bandgap energy. Perovskite absorber 716 can have any other suitable composition that achieves the target bandgap energy. Perovskite absorber 716 can be formed by spin coating, blade coating, slot-die coating, gravure coating, roll coating, spray coating, evaporation, sublimation, or any other suitable deposition process.

Hole-selective layer 718 can include one or more materials configured to conduct photogenerated holes out of perovskite absorber 716 and to resist photogenerated electrons. Hole-selective layer 718 can include a high-work-function material (e.g., nickel oxide, tungsten oxide, molybdenum oxide, Spiro-OMeTAD, poly(triaryl amine), polyTPD, PFN, PEDOT:PSS, or a combination or stack thereof).

Serial interconnection 704 is a recombination layer or junction. Serial interconnection 704 can include indium tin oxide, indium zinc oxide, hydrogenated indium oxide, indium tungsten oxide, indium cerium oxide, tin oxide, zinc oxide, zinc tin oxide, or combinations thereof that are sputtered, evaporated, spray coated, or otherwise deposited.

Perovskite bottom cell 706, from its sunward side to rear side, includes electron-selective layer 724, perovskite absorber 726, hole-selective layer 728, and transparent conductor 730. In some implementations, the positions of the electron-selective and hole-selective layers are reversed in accordance with the polarities of the contacts of perovskite top cell 702. Electron-selective layer 724 can include one or more materials configured to conduct photogenerated electrons out of perovskite absorber 726 and to resist photogenerated holes. Electron-selective layer 724 can include a low-work-function material (e.g., tin oxide, zinc oxide, titanium oxide, fullerene, fullerene derivatives, or a combination or stack thereof). Perovskite absorber 726 can have a bandgap energy in a range of about 1.2 eV to about 1.4 eV or about 1.4 eV to about 1.6 eV. Perovskite absorber 726 can have a composition represented by MAᵥFA_{w}Cs_{1-v-w}PbₓSn₁₋ₓ(I_{y}Br_{z}Cl_{1-y-z})₃, where MA represents methylammonium, FA represents formamidinium, Cs represents cesium, Pb represents lead, Sn represents tin, I represents iodide, Br represents bromine, Cl represents chlorine, and v, w, x, y, z are relative concentrations chosen to achieve the target bandgap energy. In certain implementations, perovskite absorber 726 has any other suitable composition that achieves the target bandgap energy. Perovskite absorber 726 can be formed by spin coating, blade coating, slot-die coating, gravure coating, roll coating, spray coating, evaporation, sublimation, or any other suitable deposition process. Hole-selective layer 728 can include one or more materials configured to conduct photogenerated holes out of perovskite absorber 726 and to resist photogenerated electrons. Hole-selective layer 728 can include a high-work-function material. It can include, for example, nickel oxide, tungsten oxide, molybdenum oxide, Spiro-OMeTAD, poly(triaryl amine), polyTPD, PFN, PEDOT:PSS, or a combination or stack thereof. Transparent conductor 730 can include one or more layers of materials such as indium tin oxide, indium zinc oxide, hydrogenated indium oxide, indium tungsten oxide, indium cerium oxide, tin oxide, zinc oxide, zinc tin oxide, or combinations thereof that are sputtered, evaporated, spray coated, or otherwise deposited. Transparent conductor 730 can serve to transport photogenerated holes collected in hole-selective layer 728 laterally. In some implementations, transparent conductor 730 serves as one of the electrical terminals of photovoltaic cell 700.

Superstrate 708 transmits at least the portions of the solar spectrum that perovskite absorbers 716 and 726 are configured to absorb. Superstrate 708 can include glass, plastic, or any other suitable material. In one example, superstrate 708 is heat-tempered, low-iron, soda-lime glass having a thickness in a range of about 1 mm to about 5 mm (e.g., about 3 mm).

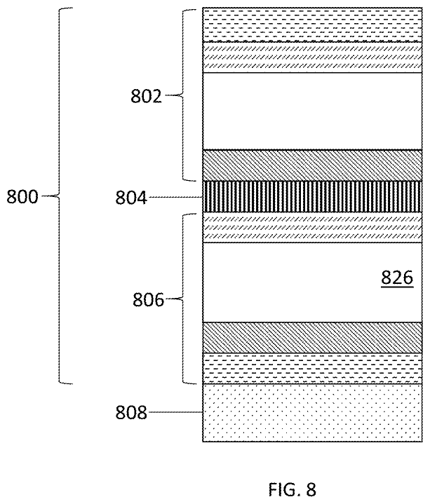

FIG. 8 is a cross-sectional view of photovoltaic cell 800 and substrate 808. Photovoltaic cell 800 includes perovskite top cell 802, serial interconnection 804, and perovskite bottom cell 806. Perovskite top cell 802 can be the same as perovskite top cell 702 or it can be different. Serial interconnection 804 can be the same as serial interconnection 704 or it can be different. Perovskite bottom cell 806 can be the same as perovskite bottom cell 706 or it can be different. Substrate 808 transmits at least the portion of the solar spectrum that perovskite absorber 826 is configured to absorb. Substrate 808 can be glass, plastic, or any other suitable material. In one example, substrate 808 is heat-tempered, low-iron, soda-lime glass with a thickness in a range of about 1 mm to about 5 mm (e.g., about 3 mm).

This disclosure also describes a bifacial tandem photovoltaic module. This photovoltaic module has a plurality of bifacial tandem photovoltaic cells that are electrically coupled. The photovoltaic module also has optically transparent outer layers that protect the photovoltaic cells from the elements.

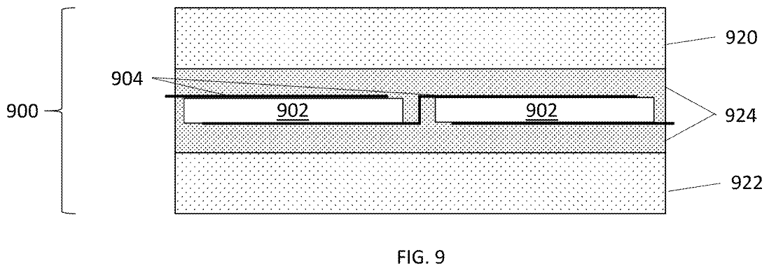

FIG. 9 is a cross-sectional view of photovoltaic module 900. Photovoltaic module 900 includes a plurality of bifacial, two-terminal tandem photovoltaic cells 902. Photovoltaic cells 902 can be freestanding prior to their incorporation into photovoltaic module 900. Photovoltaic cells 100, 200, 300, 400, 500, and 600 are examples of suitable photovoltaic cells 902 for photovoltaic module 900. In one example, at least one sub-cell in each photovoltaic cell 902 includes an absorber that is a silicon wafer. In some implementations, each photovoltaic cell 902 includes a perovskite top cell and a silicon bottom cell. Photovoltaic module 900 also includes electrical interconnections 904. Electrical interconnections 904 electrically couple photovoltaic cells 902 in series or in parallel. Series interconnections are made when the positive electrical terminal of a first photovoltaic cell 902 is electrically coupled to the negative electrical terminal of a second photovoltaic cell 902. Parallel interconnections are made when the positive electrical terminal of a first photovoltaic cell 902 is electrically coupled to the positive electrical terminal of a second photovoltaic cell 902. In some implementations, first and second photovoltaic cells 902 are adjacent (e.g., immediately adjacent, with no intervening photovoltaic cell between the first and second photovoltaic cells). Electrical interconnections 904 can include metal tabs, ribbons, wires, any other suitable electrically conductive material, or some combination thereof. Electrical interconnections 904 can be coupled to photovoltaic cells 902 by soldering, bonding with low-melting-temperature metals, bonding with electrically conductive adhesive, or any other suitable method to form an electrically conductive contact.

Photovoltaic module 900 also includes outer layers 920 and 922, and encapsulant 924. Outer layer 920 transmits at least the portions of the solar spectrum that the absorbers of the top and bottom cells of photovoltaic cells 902 are configured to absorb. Outer layer 922 transmits at least the portion of the solar spectrum that the absorber of the bottom cells of photovoltaic cells 902 are configured to absorb. Outer layers 920 and 922, when used in conjunction with other layers in photovoltaic module 900, withstand hail and wind-loading tests stipulated in photovoltaic module product qualification tests (e.g., IEC61215). Outer layers 920 and 922 can include glass, plastic, or any other suitable material. In one example, outer layers 920 and 922 are heat-tempered, low-iron, soda-lime glass. Outer layer 920 typically has a thickness in a range of about 1 mm to about 5 mm or about 1.5 mm to about 3.5 mm (e.g., about 2.5 mm). Outer layer 922 typically has a thickness in a range of about 1 mm to about 5 mm or about 1.5 mm to about 3.0 mm (e.g., about 2.0 mm). In some implementations, outer layer 920 has an anti-reflection coating. In one implementation, the anti-reflection coating includes silica particles deposited by a sol-gel or vacuum deposition process. One or more surfaces of outer layers 920 and 922 can be textured.

Encapsulant 924 transmits at least the portions of the solar spectrum that the absorbers of the top and bottom cells of photovoltaic cells 902 are configured to absorb. Encapsulant 924 can include one or more layers such as an ethylene-vinyl acetate layer, a polyolefin layer, an ionomer layer, a silicone layer, or some combination thereof. Other suitable materials include materials capable of forming an optically transparent layer with a refractive index of about 1.5. Encapsulant 924 advantageously exhibits adhesion to outer layers 920 and 922 and photovoltaic cells 902 sufficient to resist delamination after ultraviolet (UV), thermal, or moisture tests stipulated in solar module product qualification tests (e.g., IEC61215). Prior to fabrication of photovoltaic module 900, encapsulant 924 can be two or more freestanding layers or sheets, with each layer or sheet typically having a thickness in a range of about 10 μm to about 800 μm (e.g., about 150 μm to about 400 μm).

Photovoltaic module 900 can be assembled in a manner similar to that used to assemble other types of photovoltaic modules. In one example, the materials in a photovoltaic module are stacked, layer by layer, and laminated at elevated temperature or pressure. In one example, a first layer of encapsulant is placed on and aligned with a first outer layer, a string of soldered or otherwise interconnected photovoltaic cells is placed on and aligned with the first layer of encapsulant, a second layer of encapsulant is placed on and aligned with the string of photovoltaic cells, a second outer layer is placed on and aligned with the second layer of encapsulant, and the resulting stack is laminated in a vacuum laminator.

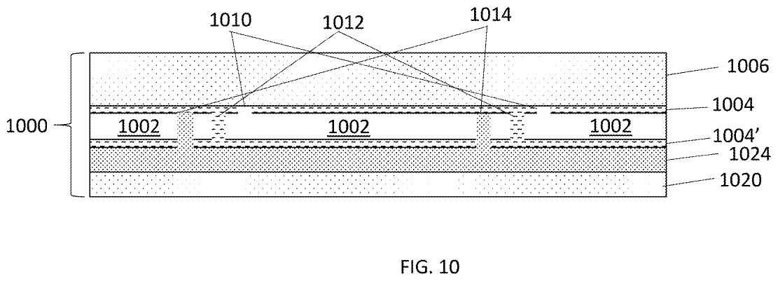

FIG. 10 is a cross-sectional view of photovoltaic module 1000. Photovoltaic module 1000 includes a plurality of bifacial, two-terminal tandem photovoltaic cells 1002. Photovoltaic cells 1002 can be fabricated directly on superstrate 1006. Photovoltaic cell 700 is an example of a suitable photovoltaic cell 1002 for photovoltaic module 1000. In one implementation, each photovoltaic cell 1002 includes a perovskite top cell and a perovskite bottom cell. Photovoltaic module 1000 also includes electrical interconnections 1004, 1004′. Electrical interconnections 1004, 1004′ electrically couple photovoltaic cells in series or in parallel. Electrical interconnections 1004, 1004′ can be optically transparent conductive oxides, metal tabs, ribbons, wires, any other suitable electrically conductive material, or some combination thereof. Electrical interconnections 1004, 1004′ can be coupled to photovoltaic cells 1002 by bonding during deposition, soldering, bonding with low-melting-temperature metals, bonding with electrically conductive adhesive, or any other suitable method to form an electrically conductive contact. In some implementations, electrical interconnection 1004, 1004′ includes two transparent conductors on photovoltaic cells 1002, and each adjacent pair of photovoltaic cells 1002 are delineated and coupled (e.g., directly connected) by openings. In one implementation, the openings are formed by laser scribing. First opening 1010 extends through electrical interconnection 1004 of the top cell of photovoltaic cell 1002 and is typically made after the deposition of electrical interconnection 1004. Second opening 1012 extends through all layers of photovoltaic cell 1002 except electrical interconnections 1004, 1004′ and is typically made after the deposition of all layers except electrical interconnections 1004′. Third opening 1014 extends through electrical interconnection 1004′ of the bottom cell of photovoltaic cell 1002 and is typically made after the deposition of electrical interconnection 1004′. Electrical interconnection 1004′ of the bottom cell contacts the electrical interconnection 1004 of the top cell through second opening 1012. The first and third openings 1010 and 1014, respectively, delineate the layers into a plurality of photovoltaic cells 1002 so that the contact of the electrical interconnections 1004, 1004′ through second opening 1012 results in serial interconnection of photovoltaic cells 1002. That is, first and third openings 1010, 1014 do not result in shunts.

Photovoltaic module 1000 can also include superstrate 1006, outer layer 1020, and encapsulant 1024. Superstrate 1006 can be the same as outer layer 920 or it can be different. Outer layer 1020 can be the same as outer layer 922 or it can be different. Encapsulant 1024 can be the same as encapsulant 924 or it can be different. Prior to fabrication of photovoltaic module 1000, encapsulant 1024 can be one or more freestanding layers or sheets. In some implementations, each freestanding layer or sheet has a thickness in a range of about 10 μm to about 800 μm (e.g., about 150 μm to about 400 μm).

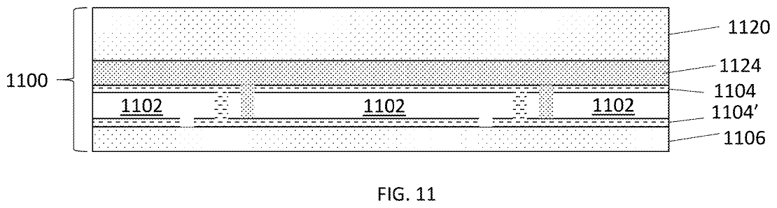

FIG. 11 is a cross-sectional view of photovoltaic module 1100. Photovoltaic module 1100 includes a plurality of bifacial, two-terminal tandem photovoltaic cells 1102. Photovoltaic cells 1102 can be fabricated on substrate 1106. Photovoltaic cell 800 is an example of a suitable photovoltaic cell 1102 for photovoltaic module 1100. In some implementations, photovoltaic cells 1102 include a perovskite top cell and a perovskite bottom cell. Photovoltaic module 1100 also includes electrical interconnections 1104, 1104′ which can be the same as electrical interconnections 1004, 1004′ or can be different. Photovoltaic module 1100 also includes outer layer 1120, which can be the same as outer layer 920 or can be different. Substrate 1106 can be the same as outer layer 922 or can be different. Photovoltaic module 1100 also includes encapsulant 1124, which can be the same as encapsulant 1024 or can be different.

Photovoltaic modules 1000 and 1100 can be assembled in a manner similar to that used to assemble other types of photovoltaic modules. In some implementations, the materials in a photovoltaic module are stacked, layer by layer, and laminated at elevated temperature or pressure. In one example, a layer of encapsulant is placed on and aligned with a superstrate or substrate having photovoltaic cells thereon, an outer layer is placed on and aligned with the layer of encapsulant, and the resulting stack is laminated in a vacuum laminator.

Although this disclosure contains many specific details, these should not be construed as limitations on the scope of the subject matter or on the scope of what may be claimed, but rather as descriptions of features that may be specific to particular implementations. Certain features that are described in this disclosure in the context of separate implementations can also be implemented, in combination, in a single embodiment. Conversely, various features that are described in the context of a single implementations can also be implemented in multiple embodiments, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example implementations do not define or constrain this disclosure. Other changes, substitutions, and alterations are also possible without departing from the spirit and scope of this disclosure.

What is claimed is:

1. A tandem photovoltaic cell comprising:
a top cell comprising a first absorber; and
a bottom cell comprising a second absorber,
wherein the top cell and the bottom cell are electrically coupled in series, and
wherein the top cell is configured to receive solar radiation through a first surface of the top cell and to transmit photons through a second surface of the top cell to the bottom cell, and the bottom cell is configured to receive the photons from the top cell through a first surface of the bottom cell and to receive solar radiation through a second surface of the bottom cell.

2. The photovoltaic cell of claim 1, wherein a bandgap energy of the first absorber exceeds a bandgap energy of the second absorber.

3. The photovoltaic cell of claim 2, wherein the bandgap energy of the first absorber is in a range between about 1.5 eV and about 2.1 eV.

4. The photovoltaic cell of claim 2, wherein the bandgap energy of the second absorber is in a range between about 1 eV and about 1.5 eV.

5. The photovoltaic cell of claim 1, wherein the bandgap energy of the first absorber exceeds an energy of the photons.

6. The photovoltaic cell of claim 1, wherein the second absorber comprises perovskite.

7. The photovoltaic cell of claim 6, wherein the first absorber comprises perovskite.

8. The photovoltaic cell of claim 1, wherein the second absorber comprises silicon.

9. The photovoltaic cell of claim 8, wherein the bottom cell is a silicon heterojunction cell, a tunnel-oxide-passivated contact (TOPCon) cell, a passivated-emitter-rear-contact (PERC) cell, or an aluminum-back-surface-field (Al-BSF) cell.

10. The photovoltaic cell of claim 8, wherein the first absorber comprises perovskite.

11. The photovoltaic cell of claim 1, wherein the second surface of the bottom cell is opposite the first surface of the top cell.

12. The photovoltaic cell of claim 1, wherein the top cell and the bottom cell are electrically coupled in series through an optically transparent, electrically conductive layer.

13. The photovoltaic cell of claim 1, wherein the top cell and the bottom cell are electrically coupled in series through doped semiconductor layers.

14. The photovoltaic cell of claim 13, wherein the doped semiconductor layers have opposite doping polarities.

15. A photovoltaic module comprising a multiplicity of tandem photovoltaic cells of claim 1,
wherein each tandem photovoltaic cell is electrically coupled to at least one other tandem photovoltaic cell of the multiplicity of tandem photovoltaic cells,
wherein a first side of the photovoltaic module is proximate the first surface of each top cell of the multiplicity of tandem photovoltaic cells, and a second side of the photovoltaic module is proximate the second surface of each bottom cell of the multiplicity of tandem photovoltaic cells.

16. The photovoltaic module of claim 15, wherein each tandem photovoltaic cell is electrically coupled to the at least one other tandem photovoltaic cell of the multiplicity of tandem photovoltaic cells with an electrically conductive material that electrically couples, through an opening between each tandem photovoltaic cell and the at least one other tandem photovoltaic cell, a first electrically conductive material on a sunward side of the multiplicity of tandem photovoltaic cells and a second electrically conductive material on a rear side of the multiplicity of tandem photovoltaic cells.

17. The photovoltaic module of claim 15, wherein each tandem photovoltaic cell is electrically coupled in parallel or in series to the at least one other tandem photovoltaic cell.

18. The photovoltaic module of claim 15, further comprising a first protective layer proximate the first side of the photovoltaic module and a second protective layer proximate the second side of the photovoltaic module, wherein the multiplicity of tandem photovoltaic cells is positioned between the first protective layer and the second protective layer.

19. The photovoltaic module of claim 18, wherein the second protective layer is configured to transmit solar radiation to the second surface of each bottom cell of the multiplicity of tandem photovoltaic cells.

20. The photovoltaic module of claim 19, wherein each bottom cell of the multiplicity of tandem photovoltaic cells is configured to receive solar radiation through the second protective layer.
